(19) United States
(12) Patent Application Publication
(10) Pub. No.: US 2026/0246236 A1
(43) Pub. Date: Aug. 20, 2026

(54) VERTICAL CAVITY LIGHT-EMITTING ELEMENT

(71) Applicant: Stanley Electric Co., Ltd., Tokyo (JP)

(72) Inventor: Masaru KURAMOTO, Tokyo (JP)

(73) Assignee: Stanley Electric Co., Ltd., Tokyo (JP)

(21) Appl. No.: 19/159,337

(22) PCT Filed: Mar. 11, 2024
(86) PCT No.: PCT/JP2024/009247

§ 371 Date: Aug. 25, 2025

(30) Foreign Application Priority Data
Mar. 15, 2023 (JP) 2023-041380

(51) Int. Cl. H01S 5/20; H01S 5/183; H01S 5/34

(52) U.S. Cl. CPC H01S 5/2009; H01S 5/18361; H01S 5/34

(57) ABSTRACT

[Problem]

Provided is a vertical-cavity-light-emitting element with a low threshold current and high efficiency.

[Solution]

A vertical-cavity-light-emitting element includes an n-type semiconductor layer formed on a first reflective mirror, an active layer made of multiple-quantum-wells formed on the n-type semiconductor layer, a last barrier layer formed on a last quantum well of the active layer, an electron-blocking layer formed on the last barrier layer, a p-type semiconductor layer formed on the electron blocking layer, a dielectric spacer layer formed on the p-type semiconductor layer, and a second reflective mirror formed on the spacer layer. A count of anti-nodes of a standing wave by emission from the active layer contained in the electron blocking layer and the p-type semiconductor layer is 1, and a count of nodes is 0 or 1. Counts of nodes and anti-nodes of the standing wave contained in the last barrier layer are each 1 or more.

### TECHNICAL FIELD

The present invention relates to a vertical cavity light-emitting element, especially a vertical cavity light-emitting element having a multiple quantum well active layer.

### BACKGROUND ART

Conventionally, there has been known a vertical cavity light-emitting element, such as a vertical cavity surface emitting laser (VCSEL), having a structure that allows light to resonate perpendicularly to a substrate surface and emits light in a direction perpendicular to the substrate surface.

In vertical cavity light-emitting elements, a multiple quantum well (MQW) structure is generally adopted in an active layer to achieve a high-efficiency light emission property with a low threshold current.

For example, Patent Document 1 discloses an end-surface emitting nitride semiconductor laser element having a structure aimed at improving internal quantum efficiency by decreasing the concentration of the electrons and the holes of a p-side optical guide layer between a last quantum well layer and an electron blocking layer.

Patent Document 2 discloses a surface-emitting semiconductor laser including first to fourth semiconductor multilayer film reflective mirrors, in which Al compositions or impurity concentrations of the semiconductor multilayer film reflective mirrors are adjusted, to promote carrier diffusion in a lateral direction at low temperatures.

Patent Document 3 discloses a vertical cavity surface emitting laser aimed at promoting the supply of current to an active region and reducing the threshold current. The vertical cavity surface emitting laser has an insulating layer with an opening, a translucent electrode covering the opening, and a reflective mirror made of a dielectric material disposed on the opening via the translucent electrode, and a conductive material is provided between the insulating layer and the reflective mirror.
Patent Document 1: JP-A-2014-131019
Patent Document 2: JP-A-2009-194102
Patent Document 3: JP-A-2011-29607

### DISCLOSURE OF THE INVENTION

### Problems to be Solved by the Invention

In the conventional vertical cavity light-emitting elements, further reduction in threshold current and improvement in light-emitting efficiency have been problems.

The inventor of this application obtained knowledge that improving the heterogeneity of the holes and the electrons in a multiple quantum well active layer leads to a significant improvement in element characteristics. The present invention has been made based on such knowledge, and the objective is to provide a vertical cavity light-emitting element with a low threshold current and high light-emitting efficiency.

### Solutions to the Problems

A vertical cavity light-emitting element according to one embodiment of the present invention includes a first reflective mirror, an n-type semiconductor layer, an active layer, a last barrier layer, an electron blocking layer, a p-type semiconductor layer, a dielectric spacer layer, and a second reflective mirror. The n-type semiconductor layer is formed on the first reflective mirror. The active layer is made of multiple quantum wells formed on the n-type semiconductor layer. The last barrier layer is formed on a last quantum well of the active layer. The electron blocking layer is made of AlGaN formed on the last barrier layer. The p-type semiconductor layer is formed on the electron blocking layer. The dielectric spacer layer is formed on the p-type semiconductor layer. The second reflective mirror is formed on the spacer layer. A count of anti-nodes and a count of nodes of a standing wave by emission from the active layer contained in the electron blocking layer and the p-type semiconductor layer are each 0 or 1, and the active layer and the last barrier layer satisfy

$$[ Math . 1 ]$$

$$\frac{{H}_{qw}}{2 ( \frac{λ}{{n}_{qw}} )} + \frac{{H}_{fb}}{( \frac{λ}{{n}_{fb}} )} \geq 0.4$$

$$where$$

$${n}_{qw} = \frac{\sum {n}_{i} \times \sum {H}_{i}}{\sum {H}_{i}}$$

Where H_{fb} and H_{qw} are respective layer thicknesses of the last barrier layer and the active layer, n_{fb} is a refractive index of the last barrier layer, and n_{qw} is an equivalent refractive index of the active layer, and Y≥0.13X+12.7 is satisfied, where X is a layer thickness of the last barrier layer in nm, and Y is an average Al composition of the electron blocking layer in %.

A vertical cavity light-emitting element according to another embodiment of the present invention includes a first reflective mirror, a first n-type semiconductor layer, an active layer, a last barrier layer, an electron blocking layer, a p-type semiconductor layer, a tunnel junction layer, a second n-type semiconductor layer, and a second reflective mirror. The first n-type semiconductor layer is formed on the first reflective mirror. The active layer is made of multiple quantum wells formed on the first n-type semiconductor layer. The last barrier layer is formed on a last quantum well of the active layer. The electron blocking layer is made of AlGaN formed on the last barrier layer. The p-type semiconductor layer is formed on the electron blocking layer. The tunnel junction layer as a current confinement layer is formed on the p-type semiconductor layer. The second n-type semiconductor layer is formed by embedding the tunnel junction layer. The second reflective mirror is formed on the second n-type semiconductor layer. A count of anti-nodes and a count of nodes of a standing wave by emission from the active layer contained in the electron blocking layer and the p-type semiconductor layer are each 0 or 1, and the active layer and the last barrier layer satisfy

$$[ Math . 2 ]$$

$$\frac{{H}_{qw}}{2 ( \frac{λ}{{n}_{qw}} )} + \frac{{H}_{fb}}{( \frac{λ}{{n}_{fb}} )} \geq 0.4$$

$$where$$

$${n}_{qw} = \frac{\sum {n}_{i} \times \sum {H}_{i}}{\sum {H}_{i}}$$

Where H_{fb} and H_{qw} are respective layer thicknesses of the last barrier layer and the active layer, n_{fb} is a refractive index of the last barrier layer, and n_{qw} is an equivalent refractive index of the active layer, and Y≥0.13X+12.7 is satisfied, where X is a layer thickness of the last barrier layer in nm, and Y is an average Al composition of the electron blocking layer in %.

### BRIEF DESCRIPTION OF THE DRAWINGS

FIG. 1 is a cross-sectional view schematically illustrating a structure of a vertical cavity surface emitting laser 10 according to a first embodiment of the present invention.

FIG. 2 is a diagram schematically illustrating a band structure of a conduction band of the vertical cavity surface emitting laser 10.

FIG. 3 is a diagram schematically illustrating a standing wave SW in semiconductor layers from an active layer 15 to a dielectric DBR 25 in the vertical cavity surface emitting laser 10 of Example 1 (Ex. 1).

FIG. 4 is a diagram schematically illustrating the standing wave SW in semiconductor layers from an active layer to a dielectric DBR in a vertical cavity surface emitting laser of Comparative Example 1 (Cmp. 1).

FIG. 5 is a table showing layer thicknesses of the semiconductor layers, the number N_{ND} of nodes ND, and the number N_{AN} of anti-nodes AN for vertical cavity surface emitting lasers 10 of Examples 1 to 3 (Ex. 1 to Ex. 3) and vertical cavity surface emitting lasers of Comparative Examples 1 and 2 (Cmp. 1 and Cmp. 2).

FIG. 6A is a graph showing optical output relative to injection current of the vertical cavity surface emitting laser 10 of Example 1 (Ex. 1).

FIG. 6B is a graph showing voltage relative to injection current of the vertical cavity surface emitting laser 10 of Example 1 (Ex. 1).

FIG. 6C is a graph showing differential resistance relative to injection current of the vertical cavity surface emitting laser 10 of Example 1 (Ex. 1).

FIG. 7A is a graph showing optical output relative to injection current of the vertical cavity surface emitting laser of Comparative Example 1 (Cmp. 1).

FIG. 7B is a graph showing voltage relative to injection current of the vertical cavity surface emitting laser of Comparative Example 1 (Cmp. 1).

FIG. 7C is a graph showing differential resistance relative to injection current of the vertical cavity surface emitting laser of Comparative Example 1 (Cmp. 1).

FIG. 8A is a drawing showing the calculation results of an electron concentration distribution of each well layer during laser oscillation of the surface emitting laser 10 of Example 1.

FIG. 8B is a drawing showing the calculation results of the electron concentration distribution of each well layer during laser oscillation of the surface emitting laser of Comparative Example 1.

FIG. 9 is a diagram schematically illustrating the standing wave SW in the semiconductor layers from the active layer 15 to the dielectric DBR 25 in the vertical cavity surface emitting laser 10 of Example 2.

FIG. 10A is a drawing showing the calculation results of the electron concentration distribution of each well layer during laser oscillation of the surface emitting laser 10 of Example 2.

FIG. 10B is a drawing showing the calculation results of the electron concentration distribution of each well layer during laser oscillation of the surface emitting laser of Comparative Example 2.

FIG. 11 is a drawing showing the calculation results of the electron concentration distribution of each well layer during laser oscillation of the surface emitting laser 10 of Example 3.

FIG. 12 is a cross-sectional view schematically illustrating a structure of a vertical cavity surface emitting laser 50 according to a second embodiment of the present invention.

FIG. 13 is a graph showing a change in the electron concentration of a p-type semiconductor layer of a vertical cavity surface emitting laser of the present invention.

### DESCRIPTION OF PREFERRED EMBODIMENTS

While the following describes preferred embodiments of the present invention, these embodiments may be appropriately modified and combined. In the following description and attached drawings, same reference numerals are given to actually same or equivalent parts for the description.

### First Embodiment

FIG. 1 is a cross-sectional view schematically illustrating a structure of a vertical cavity surface emitting laser 10 according to a first embodiment of the present invention. In this embodiment, the vertical cavity surface emitting laser 10 is a nitride surface emitting laser made of gallium-nitride-based (GaN-based) semiconductor layers.

The vertical cavity surface emitting laser 10 is formed by crystal growth of a semiconductor distributed Bragg reflector (DBR) 12, an n-type semiconductor layer 13, an active layer 15 made of multiple quantum wells, a last barrier layer 16, an electron blocking layer (EBL) 17, and a p-type semiconductor layer 18 on a substrate 11 sequentially in this order.

The substrate 11 is a GaN substrate, which is a c-plane GaN substrate that is tilted 0.5° from the c-plane in an m-plane direction and 0±0.1° in an a-plane direction.

Metal-organic chemical vapor deposition (MOVPE) method was used to conduct the crystal growth of the semiconductor layers. On the substrate 11, a base GaN layer 11B with a layer thickness of about 1 μm was grown, and the semiconductor DBR 12 as a distributed Bragg reflector mirror was formed on the base GaN layer 11B.

The semiconductor DBR 12 (first reflective mirror) was formed by stacking 42 pairs of n-type GaN films and AlInN films. Each semiconductor film of the semiconductor DBR 12 has a film thickness of λ/4n (n is the refractive index of each semiconductor film) of an emission wavelength λ of the active layer 15.

The n-type semiconductor layer 13 (layer thickness: 350 nm) as an n-type GaN layer doped with silicon (Si) was grown on the semiconductor DBR 12.

A blocking layer (barrier layer) 15B and a quantum well layer (well layer) 15W were alternately formed on the n-type semiconductor layer 13 to form the active layer 15 having four quantum well layers 15W. The barrier layer 15B is made of GaInN (layer thickness: 3 nm), and the well layer 15W is made of GaN (layer thickness: 4 nm). The composition and layer thickness of the barrier layer 15B and the well layer 15W can be appropriately selected according to the desired emission wavelength, light emission property, and the like.

Undoped GaN was grown as the last barrier layer (LB) 16 with a layer thickness of 120 nm on a last well layer 15WL as the last layer of the active layer 15.

Next, the electron blocking layer (EBL) 17 made of Mg (magnesium-doped AlGaN (Al composition: 0.30)) with a layer thickness of 10 nm was grown. Subsequently, a p-GaN layer was grown to 83 nm as the p-type semiconductor layer 18 on the electron blocking layer 17 (p-AlGaN).

An outer peripheral portion of the wafer grown as described above was etched to reach the inside of the n-type semiconductor layer 13, forming a cylindrical mesa structure.

An outer peripheral portion of the p-type semiconductor layer 18 as the uppermost semiconductor layer of the mesa structure was etched at a depth of about 20 nm by dry etching to form a recessed portion, and the p-type semiconductor layer 18 having a cylindrical mesa projecting portion was formed.

An insulating film (SiO₂) 21 for lateral current and optical confinement was deposited with a thickness of 20 nm in the recessed portion of the p-type semiconductor layer 18 formed by etching. As a result, the recessed portion of the p-type semiconductor layer 18 was flattened, a current confinement structure was formed, and a cylindrical (central axis: CX) current injection region was formed.

Next, an indium tin oxide (ITO) film with a thickness of 20 nm was formed as a transparent conductive film 22 on the p-type semiconductor layer 18 and the insulating film 21.

Subsequently, a dielectric (Nb₂O₅) with a thickness of 38 nm was formed as a spacer layer 24. The spacer layer 24 functions as a phase adjustment layer.

Furthermore, a dielectric DBR 25 (second reflective mirror) was formed on the spacer layer 24. The dielectric DBR 25 is made of 10.5 pairs of SiO₂ (11 layers) and Nb₂O₅ (10 layers). The dielectric DBR 25 is preferably formed to be coaxial with the cylindrical mesa of the p-type semiconductor layer 18.

Next, an n-electrode 27 was formed on a recessed portion at an outer peripheral portion of the n-type semiconductor layer 13, and a p-electrode 28 was formed on the transparent conductive film 22. In addition, a backside surface of the substrate 11 was polished to form an AR (non-reflective) coating 29 made of two layers of Nb₂O₅/SiO₂. As described above, the formation of the vertical cavity surface emitting laser 10 was completed.

The composition and layer thickness of the last barrier layer (LB) 16 described above are only examples. That is, although the last barrier layer 16 has been described as a GaN layer, nitride semiconductor layers with other compositions, such as InGaN, AlGaN, and InAlGaN, may be used. In addition, although the last barrier layer 16 has been described as an undoped layer, dopants diffused from the electron blocking layer 17 or the p-type semiconductor layer 18 may be mixed in.

Moreover, the composition and layer thickness of the electron blocking layer 17 are only examples. The electron blocking layer 17 may have, for example, a layer thickness of 3 nm to 30 nm, and the Al composition may be adjusted in the range of 10% to 70%.

Although the electron blocking layer 17 has been described as a p-type semiconductor layer (p-AlGaN), it may be a p-type semiconductor layer that grows as an i-layer and has dopants diffused from the p-type semiconductor layer 18 mixed in.

In addition, the case where the active layer 15 has four quantum well layers 15W has been illustrated as an example, but it is only necessary to have a plurality of quantum well layers.

Furthermore, the p-type semiconductor layer 18 may be constituted of a plurality of semiconductor layers, including layers with different compositions and/or doping concentrations from one another and an undoped layer. Similarly, the n-type semiconductor layer 13 may also be constituted of a plurality of semiconductor layers.

The case where the dielectric DBR 25 is made of SiO₂ films and Nb₂O₅ films has been illustrated as an example, but it may be constituted of dielectric films with different refractive indices from one another by other combinations. In addition, it may be constituted of semiconductor DBRs constituted of semiconductor films with different refractive indices from one another.

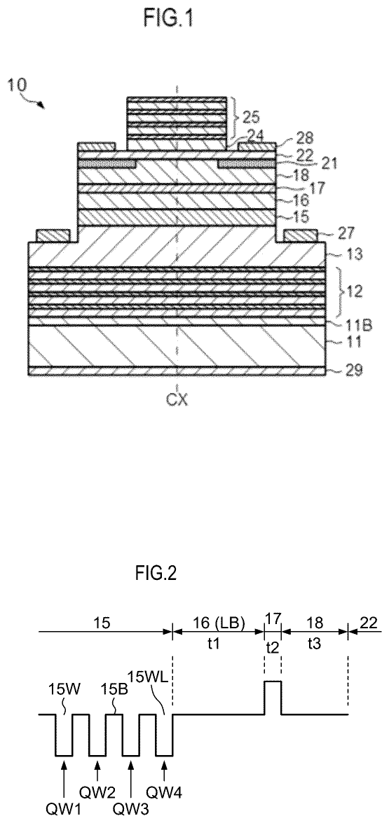

FIG. 2 is a diagram schematically illustrating a band structure of a conduction band of the vertical cavity surface emitting laser 10. The band structure from the active layer 15 to the p-type semiconductor layer 18 is illustrated.

The active layer 15 is made of four well layers 15W of QW1 to QW4 and the barrier layers 15B disposed between them. The quantum well layer QW4 adjacent to the last barrier layer (LB) 16 is the last well layer 15WL.

The last barrier layer 16 has a layer thickness t1, the electron blocking layer 17 has a layer thickness t2, and the p-type semiconductor layer 18 has a layer thickness t3.

### [Conditions of High-Efficiency Vertical Cavity Light-Emitting Element]

The inventor of this application obtained knowledge about the conditions that should be satisfied for a high-efficiency vertical cavity light-emitting element with low internal loss.

That is, first, a first interface between a high-reflective mirror, such as a distributed Bragg reflector (DBR) or a diffraction grating, and the inside of a resonator is defined as phase “0” (reference).

Using a refractive index nᵢ and a layer thickness tᵢ of each layer in the resonator and the emission wavelength λ, the total phase information of a standing wave in the resonator is represented by Equation (1) below.

$$[ Math . 3 ]$$

$${\sum }_{i = 1}^{n} \frac{{t}_{i}}{( \frac{λ}{{n}_{i}} )} \qquad ( 1 )$$

The synthesis information of the standing wave at a predetermined position inside a layer is considered by replacing the thickness from the interface with another layer on the resonator side to the predetermined position with tᵢ.

A first condition is that the number N_{AN} of anti-nodes AN and the number N_{ND} of nodes ND of a standing wave SW contained in the p-type semiconductor layer 18 and the electron blocking layer 17 that serve as a p-region are each 0 or 1 (N_{AN}=0 or N_{AN}=1, N_{ND}=0 or N_{ND}=1).

Note that it is preferable to satisfy the following Equation (2), where HITO, H_{GaN}, and H_{EB} are the respective layer thicknesses of the transparent conductive film 22 (ITO), the p-type semiconductor layer 18, and the electron blocking layer 17, n_{ITO}, n_{GaN}, and n_{EB} are the respective refractive indices of the transparent conductive film 22 (ITO), the p-type semiconductor layer 18, and the electron blocking layer 17, and λ is a wavelength.

$$[ Math . 4 ]$$

$$\frac{{H}_{ITO}}{2 ( \frac{λ}{{n}_{ITO}} )} + \frac{{H}_{GaN}}{2 ( \frac{λ}{{n}_{GaN}} )} + \frac{{H}_{EB}}{2 ( \frac{λ}{{n}_{EB}} )} \leq 0.6 \qquad ( 2 )$$

Furthermore, a second condition is that each of the numbers of nodes ND and anti-nodes AN of the standing wave SW contained in the last barrier layer 16 is 1 or more (N_{ND}≥1 and N_{AN}≥1).

The numbers N_{ND}, N_{AN} of nodes ND and anti-nodes AN of the standing wave SW can be determined by calculating each total phase in the p-region and the last barrier layer 16 using the above Equation (1) and identifying the number of points where the phase equals kπ (k=1, 2, . . . ) in the p-region and the last barrier layer 16 and the number of points where the phase equals (2l−1)π/2 (l=1, 2, . . . ).

Equation (1)=k/2 (k=1, 2, . . . ) indicates positions where the standing wave forms the anti-nodes AN, and Equation (1)=(2l−1)/4 (l=1, 2, . . . ) indicates positions where the standing wave forms the nodes ND. That is, N_{ND} and N_{AN} in the p-type semiconductor layer 18, the electron blocking layer 17, and the last barrier layer 16 are determined by counting the number of positions that become the above-described anti-nodes AN and the number of positions that become the nodes ND included in a stacking range of the respective layers.

In addition, it is preferable to satisfy the following Equation (3), where H_{fb} and H_{qw} are the respective layer thicknesses of the last barrier layer 16 and the active layer 15. Here, n_{fb} is the refractive index of the last barrier layer 16, and n_{qw} is the equivalent refractive index of the active layer 15.

$$[ Math . 5 ]$$

$$\frac{{H}_{qw}}{2 ( \frac{λ}{{n}_{qw}} )} + \frac{{H}_{fb}}{( \frac{λ}{{n}_{fb}} )} \geq 0.4 \qquad ( 3 )$$

$$where$$

$${n}_{qw} = \frac{\sum {n}_{i} \times \sum {H}_{i}}{\sum {H}_{i}}$$

Furthermore, (i) the last barrier layer 16 preferably has a layer thickness of λ/4 or more. That is, it is preferable to satisfy Equation (4) below.

$$[ Math . 6 ]$$

$$\frac{{H}_{fb}}{( \frac{λ}{{n}_{fb}} )} \geq \frac{1}{4} \qquad ( 4 )$$

Moreover, (ii) the number of nodes ND contained in the last barrier layer 16 is preferably 2 or more (N_{ND}≥2), and the number of anti-nodes AN contained in the last barrier layer 16 is preferably 1 or more (N_{AN}≥1). When (i) and (ii) are satisfied, it is further preferable to satisfy Equation (5) below.

$$[ Math . 7 ]$$

$$\frac{{H}_{fb}}{( \frac{λ}{{n}_{fb}} )} \geq \frac{3}{8} \qquad ( 5 )$$

In addition, the layer thickness of the active layer 15 is preferably λ/8 or less, that is, it is preferable to satisfy Equation (6) below. In this case, the optical confinement loss of the active layer 15 can be reduced.

$$[ Math . 8 ]$$

$$\frac{{H}_{qw}}{2 ( \frac{λ}{{n}_{qw}} )} \leq \frac{1}{8} \qquad ( 6 )$$

Configuring as described above enhances the electric field intensity of light from the p-type semiconductor layer 18 to the electron blocking layer 17. In addition, the presence of an anti-node AN with high electric field intensity of light in the last barrier layer 16 and the presence of at least one node ND in the last barrier layer 16 excite the active layer 15 enough to obtain a large optical gain.

Furthermore, when the internal optical intensity is enhanced by the semiconductor DBR 12 and the dielectric DBR 25 as high-reflective mirrors, the electrons and the holes in the last barrier layer 16 are excited by the internal light, and the holes accumulated at the interface between the electron blocking layer 17 and the p-type semiconductor layer 18 are pulled out to the active layer 15, resulting in the hole injection into the active layer 15 in a switching manner.

As a result, the homogeneity of respective carriers (the electrons and the holes) in the plurality of well layers 15W of the active layer 15 can be improved, thereby realizing an efficient surface emitting laser.

### [Consideration of Mechanism for Property Improvement]

By configuring as described above, the homogeneity of the respective carriers (the electrons and the holes) in the well layers 15W of the active layer 15 can be improved, thereby realizing an efficient surface emitting laser. The mechanism that can thus improve properties, such as efficiency, is considered.

The mechanism for improving properties is considered to be related to the injection of the holes in a switching manner in order to solve carrier heterogeneity of the multiple quantum wells. This surface emitting laser is designed with anti-nodes of the standing wave aligned in the center of the active layer (multiple quantum wells). That is, by arranging the active layer where the electric field of light is large, the interaction between the light and electron-hole recombination is increased.

Therefore, the last barrier layer 16 adjacent to the active layer 15 is in a direction where the electric field intensity of light decreases. However, by arranging the last barrier layer 16 in which the anti-nodes of the standing wave different from those of the active layer are positioned as described above or in which the neighborhood of the anti-nodes is included, it is presumed that the optical intensity of this layer rises significantly near a threshold, and carriers (the electrons and the holes) are generated, exhibiting the effect of drawing the holes on the p-type semiconductor layer 18 side of the electron blocking layer 17 at once. This drawing is more likely to occur when the electrical field gradient in the p-region is high.

This effect is considered to be caused by the increase in the concentration of the holes accumulated on the p-type semiconductor layer 18 side and the increase of the electrical field gradient in the electron blocking layer 17. The switching of the hole drawing is considered to improve the homogeneity of carrier distribution in the multiple quantum wells and reduce the internal loss. Accordingly, in some cases, due to laser oscillation, properties that are not seen in the properties of an ordinary surface emitting laser (VCSEL), such as the local minimal value of differential resistance and drive current (dR/dI=0, d²V/dI²=0) near the threshold can be obtained. Therefore, the position of the anti-nodes in the last barrier layer 16, the thinning of a p-layer (the electron blocking layer 17 and the p-type semiconductor layer 18), and the optical intensity in which there are strong vertical light feedback and optical gain by the high-reflective mirrors are important factors.

### Example 1

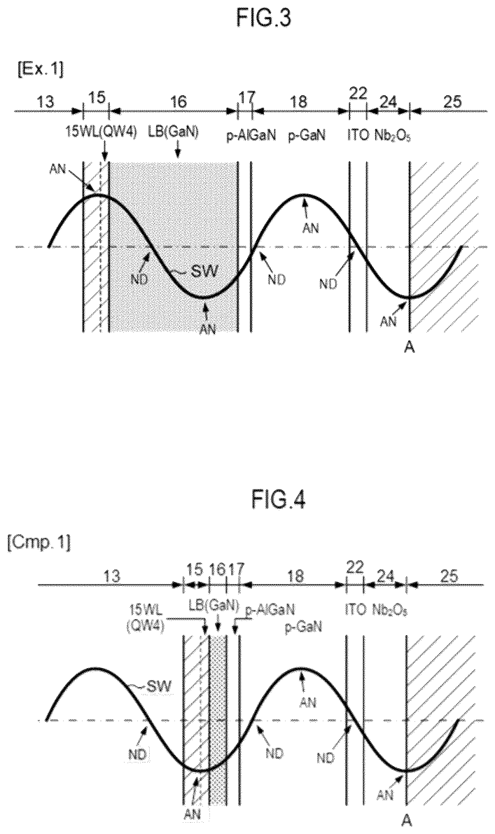

FIG. 3 is a diagram schematically illustrating the standing wave SW with the electric field intensity of the emission from the active layer 15 in the semiconductor layers from the active layer 15 to the dielectric DBR 25 in the vertical cavity surface emitting laser 10 of Example 1 (Ex. 1) of this embodiment.

In Example 1 (Ex. 1), one node ND and one anti-node AN of the standing wave SW are present in the last barrier layer 16. That is, N_{ND}=1 and N_{AN}=1, where N_{ND} is the number of nodes ND, and N_{AN} is the number of anti-nodes AN. As illustrated in FIG. 3, the standing wave SW has an anti-node AN at a high-reflective mirror interface A with the dielectric DBR 25.

In addition, one node ND and one anti-node AN of the standing wave SW are present (N_{ND}=1, N_{AN}=1) in the electron blocking layer (EBL) 17 and the p-type semiconductor layer (p-GaN) 18 that serve as the p-region. Furthermore, one node ND of the standing wave SW is preferably present (N_{ND}=1) in the transparent conductive film (ITO) 22.

Configuring as described above enhances the electrical field intensity from the p-type semiconductor layer 18 to the electron blocking layer 17. In addition, the presence of an anti-node with high electric field intensity of light in the last barrier layer 16 and the presence of at least one node in the last barrier layer 16 excite the active layer 15 enough to obtain a large optical gain.

Furthermore, when the internal optical intensity is enhanced by the semiconductor DBR 12 and the dielectric DBR 25 as high-reflective mirrors, the electrons and the holes in the last barrier layer 16 are excited by the internal light, and the holes accumulated at the interface between the electron blocking layer 17 and the p-type semiconductor layer 18 are pulled out to the active layer 15, resulting in the hole injection into the active layer 15 in a switching manner.

As a result, the homogeneity of the carriers (the electrons and the holes) in the four well layers 15W (QW1 to QW4) can be improved, thereby realizing an efficient surface emitting laser.

### Comparative Example 1

FIG. 4 is a diagram schematically illustrating the standing wave SW with the electric field intensity of light in the semiconductor layers from the active layer 15 to the dielectric DBR 25 in a vertical cavity surface emitting laser of Comparative Example 1 (Cmp. 1). FIG. 5 is a table showing the layer thicknesses of the semiconductor layers, the number N_{ND} of nodes ND, and the number N_{AN} of anti-nodes AN for vertical cavity surface emitting lasers 10 of Examples 1 to 3 (Ex. 1 to Ex. 3) of this embodiment and vertical cavity surface emitting lasers of Comparative Examples 1 and 2 (Cmp. 1 and Cmp. 2).

The vertical cavity surface emitting laser of Comparative Example 1 (Cmp. 1) significantly differs from the vertical cavity surface emitting laser 10 of Example 1 (Ex. 1) in that the last barrier layer (LB) 16 has a layer thickness of 10 nm. That is, in the vertical cavity surface emitting laser of Comparative Example 1, neither nodes ND nor anti-nodes AN of the standing wave SW are present (N_{ND}=0, N_{AN}=0) in the last barrier layer 16. Except for the difference in film thickness described in FIG. 5, Comparative Example 1 shares a common configuration with Example 1.

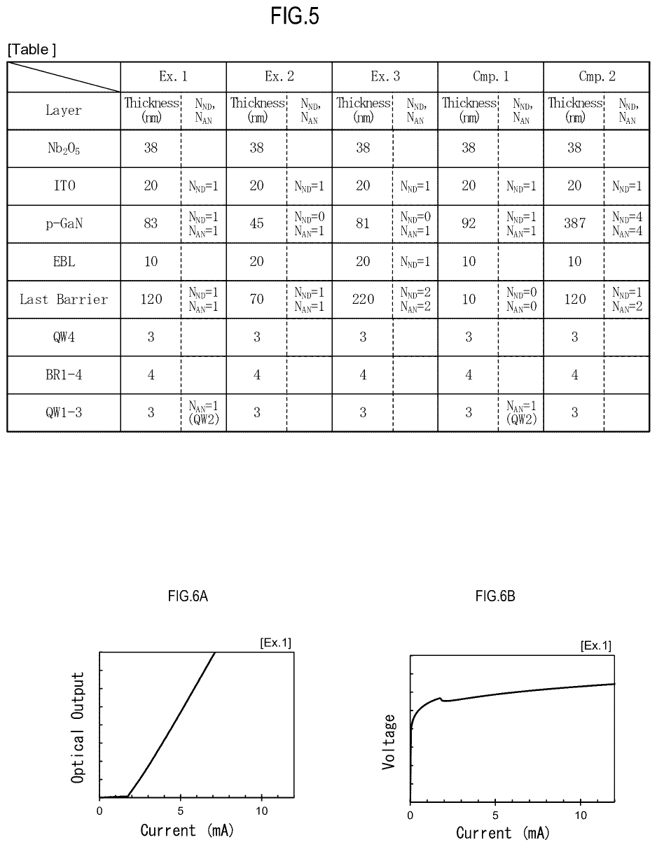

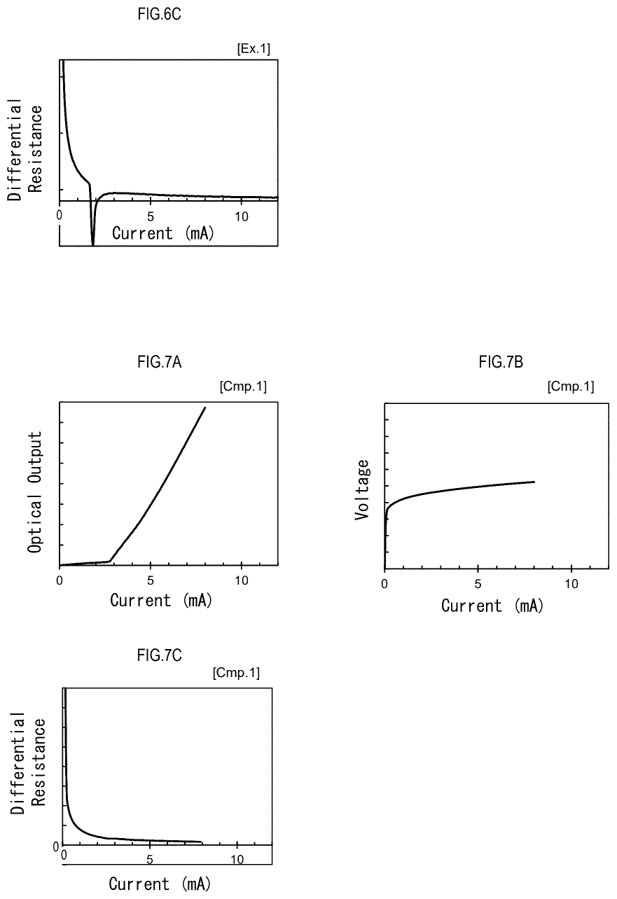

FIGS. 6A, 6B, and 6C are graphs showing the measurement results of the vertical cavity surface emitting laser 10 of Example 1 (Ex. 1) and show the properties of optical output, voltage, and differential resistance relative to injection current, respectively. FIGS. 7A, 7B, and 7C are graphs showing the measurement results of the vertical cavity surface emitting laser of Comparative Example 1 (Cmp. 1) and show the properties of optical output, voltage, and differential resistance relative to injection current, respectively.

As shown in FIG. 6A, the laser oscillation property at a low threshold current was confirmed in the vertical cavity surface emitting laser 10 of Example 1 (Ex. 1). In addition, as shown in Table 1 below, slope efficiency and external differential quantum efficiency were improved compared to the vertical cavity surface emitting laser of Comparative Example 1 (Cmp. 1).

TABLE 1

| | Slope Efficiency | External Differential | Internal Loss |
|---|---|---|---|
| | (W/A) | Quantum Efficiency (%) | (cm⁻¹) |
| Example 1 | 1.65 | 61 | 8 |
| (Ex. 1) | | | |
| Comparative | 1.5 | 55 | 17 |
| Example 1 | | | |
| (Cmp. 1) | | | |

As shown in Table 1 below, in Comparative Example 1, the slope efficiency and external differential quantum efficiency are lower than those of Example 1. As a result of an analysis, it was found that the internal loss of the laser of Comparative Example 1 was higher than that of Example 1. The internal loss of the laser of Comparative Example 1 was a value equal to the internal loss conventionally reported. Further, the I-V characteristics of Comparative Example 1 exhibit behavior similar to the I-V characteristics described in documents of the prior art. In the prior art, the local minimal value or negative resistance of differential resistance near the threshold current is not observed.

Specifically, as shown in FIGS. 6B and 6C, in the vertical cavity surface emitting laser 10 of this embodiment, there were devices in which voltage fluctuations were observed near the threshold current. It was found that the differential resistance drops sharply near the threshold current, and the differential resistance and the drive current have a local minimal value (dR/dI=0, d²V/dI²=0, R: resistance, I: current) in some cases. In addition, if it is even more intense, the differential resistance may enter the negative region.

Such properties are not observed in conventional surface emitting lasers. In the vertical cavity surface emitting laser 10 of this embodiment, it is considered that in a state where the thickness of the p-region (the electron blocking layer 17 and the p-type semiconductor layer 18) is thin and a large electrical field is applied to the p-region layers, the holes accumulated at the interface between the electron blocking layer 17 and the p-type semiconductor layer 18 (p-GaN) are induced by the electrons and the holes generated in the last barrier layer 16 and flow into the active layer 15 all at once. This facilitates the homogeneity of carrier concentrations between the multiple quantum wells, allowing the internal loss, external differential quantum efficiency, and slope efficiency to improve, and achieving the reduction and the local minimal value of the differential resistance near the threshold current.

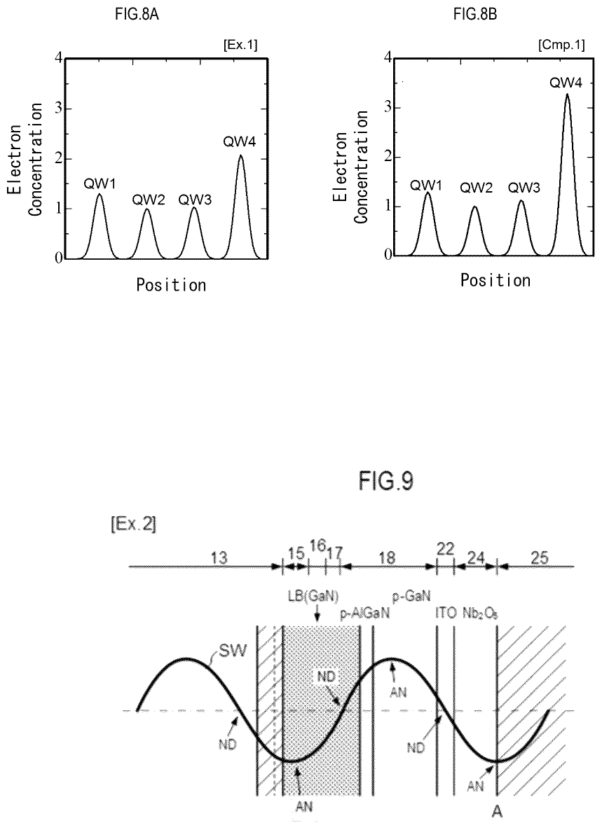

More specifically, the reduction of the internal loss is considered to be due to the homogenization of the carrier density distribution of each well layer 15W. FIGS. 8A and 8B show the calculation results of the carrier density (electron concentration) distribution of each well layer 15W during laser oscillation of the surface emitting lasers of Example 1 and Comparative Example 1, respectively.

FIGS. 8A and 8B show the electron concentrations standardized by defining that of the well layer (QW2) with the lowest carrier density as 1. It can be seen that the heterogeneity is three times or more in Comparative Example 1, while it is reduced to about two times in Example 1. Since this heterogeneity causes an optical loss in the well layer (QW2) with the lowest carrier density, the internal loss is considered to be increased.

In conventional surface emitting lasers, it is considered that the external differential quantum efficiency is low, and the differential resistance before laser oscillation is high because the holes are difficult to move due to the presence of the holes with large effective mass and a piezoelectric field, resulting in heterogeneity of the holes and the electrons in multiple quantum well layers.

In Comparative Example 1, since one node ND and one anti-node AN are present (N_{ND}=1, N_{AN}=1) in the p-region (the electron blocking layer 17 and the p-type semiconductor layer 18), the first condition is satisfied. However, neither nodes ND nor anti-nodes AN are present (N_{ND}=0, N_{AN}=0) in the last barrier layer 16, and the second condition is not satisfied. It is important to satisfy the first condition and the second condition.

In the vertical cavity surface emitting laser 10 of this embodiment, by the effects described above, the effect of reducing the internal loss is obtained, and the differential resistance is reduced near the threshold current. In addition, the differential resistance and the drive current have a local minimal value (dR/dI=0, d²V/dI²=0) near the threshold current in some cases.

The emission spectrum and gain spectrum before laser oscillation can be widely distributed even on the high-energy side according to the Fermi-Dirac distribution function. It is preferable to have a gain peak and emission peak on the higher-energy (shorter wavelength) side than the oscillation wavelength. Furthermore, it is preferable to have a thick well layer thickness of, for example, 4 nm or more, so that a second level (quantum level in the conduction band) is formed in the quantum wells.

It is possible to confirm whether the emission peak is on the high-energy side by observing the optical spectrum before oscillation and confirming that the optical intensity or the energy is larger on the shorter wavelength side than the oscillation wavelength. In addition, by utilizing this hole injection effect, photo-excitation is conducted while maintaining the current fixed before the laser oscillation, thereby facilitating the occurrence of an optical switching phenomenon or causing self-pulsation operation with a surface emitting laser.

When the optical switching phenomenon is utilized, a current slightly below the threshold current is supplied by a power source (not illustrated) connected to the vertical cavity surface emitting laser 10, so that the vertical cavity surface emitting laser 10 is irradiated with light from the outside. The light from the outside can be emitted by using a light source other than the vertical cavity surface emitting laser 10.

### Example 2

In Example 1 (Ex. 1), the case where one node ND and one anti-node AN of the standing wave SW are present (N_{ND}=1, N_{AN}=1) in the last barrier layer 16, and one node ND and one anti-node AN are present (N_{ND}=1, N_{AN}=1) in the p-region (the electron blocking layer 17 and the p-type semiconductor layer 18) has been described.

A structure of the vertical cavity surface emitting laser 10 of Example 2 (Ex. 2) is described with reference to FIG. 9. FIG. 9 is a diagram schematically illustrating the standing wave SW with the electric field intensity of light in the semiconductor layers from the active layer 15 to the dielectric DBR 25 in the vertical cavity surface emitting laser 10 of Example 2.

As shown in FIG. 5, in Example 2, the layer thickness of the last barrier layer 16 is 70 nm, which is thinner than 120 nm in Example 1. In addition, the layer thickness of the p-region (the total layer thickness of the electron blocking layer 17 and the p-type semiconductor layer 18) is 65 nm (20+45 nm), which is thinner than 93 nm (10+83 nm) in Example 1.

The Al composition of the electron blocking layer 17 was set to 0.15. Except for the above points, Example 2 is similar to Example 1.

In the vertical cavity surface emitting laser 10 of Example 2, one node ND and one anti-node AN are present (N_{ND}=1, N_{AN}=1) in the last barrier layer 16. One anti-node AN is present, and no nodes ND are present (N_{AN}=1, N_{ND}=0) in the p-region (the electron blocking layer 17 and the p-type semiconductor layer 18).

### Comparative Example 2

The vertical cavity surface emitting laser of Comparative Example 2 (Cmp. 2) significantly differs from the vertical cavity surface emitting lasers 10 of Example 1 (the layer thickness of the p-region: 93 nm) and Example 2 (the layer thickness of the p-region: 65 nm) in that the layer thickness of the p-region (the total layer thickness of the electron blocking layer 17 and the p-type semiconductor layer 18) is as thick as 397 nm (10+387 nm). Except for the above point, Comparative Example 2 is similar to Example 1.

As shown in FIG. 5, in the vertical cavity surface emitting laser of Comparative Example 2, one node ND and two anti-nodes AN of the standing wave SW are present (N_{ND}=1, N_{AN}=2) in the last barrier layer 16. In addition, four nodes ND and four anti-nodes AN are present (N_{ND}=4, N_{AN}=4) in the p-region (the electron blocking layer 17 and the p-type semiconductor layer 18).

That is, although the above-described second condition (the numbers of nodes ND and anti-nodes AN contained in the last barrier layer 16) is satisfied, the first condition (the numbers of nodes ND and anti-nodes AN contained in the electron blocking layer 17 and the p-type semiconductor layer 18) is not satisfied.

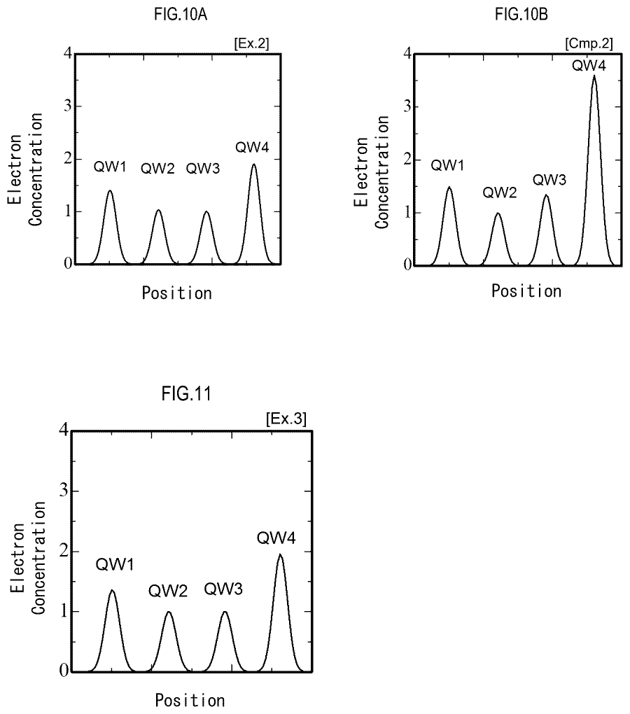

FIGS. 10A and 10B show the calculation results of the carrier density (electron concentration) distribution of each well layer 15W during laser oscillation of the surface emitting lasers of Example 2 and Comparative Example 2, respectively.

FIGS. 10A and 10B show the electron concentrations standardized by defining that of the well layer (QW2) with the lowest carrier density as 1. It can be seen that the heterogeneity is 3.5 times or more in Comparative Example 2, while it is reduced to about two times in Example 2.

Since this heterogeneity causes an optical loss in the well layer (QW2) with the lowest carrier density, the internal loss is considered to be increased.

From the above, it can be seen that an efficient surface emitting laser cannot be obtained only by satisfying the condition of the last barrier layer (the second condition).

In addition, although slightly, the carrier homogeneity is higher in Example 2 than in Example 1, and in the electron blocking layer 17 and the p-type semiconductor layer 18, N_{ND}=0 and N_{AN}=1 are preferable to N_{ND}=1 and N_{AN}=1.

### Example 3

As shown in FIG. 5, in Example 3 (Ex. 3), the layer thickness of the last barrier layer 16 is 220 nm, which is thicker than 120 nm in Example 1. In addition, the layer thickness of the p-region (the total layer thickness of the electron blocking layer 17 and the p-type semiconductor layer 18) is 101 nm (20+81 nm), which is thicker than 93 nm (10+83 nm) in Example 1. The Al composition of the electron blocking layer 17 was set to 0.15. Except for the above points, Example 3 is similar to Example 1.

In Example 3, two nodes ND and two anti-nodes AN are present (N_{ND}=2, N_{AN}=2) in the last barrier layer 16, reflecting the fact that the last barrier layer 16 is thick. In addition, one node ND and one anti-node AN are present (N_{ND}=1, N_{AN}=1) in the p-region (the electron blocking layer 17 and the p-type semiconductor layer 18).

FIG. 11 shows the calculation result of the carrier density (electron concentration) distribution of each well layer 15W during laser oscillation of the surface emitting laser 10 of Example 3.

It was confirmed that the homogeneity improved significantly compared with Comparative Example 1 and Comparative Example 2. In addition, Example 3 was slightly improved compared with Example 1, and it was found that the target high-efficiency surface emitting laser can be realized even with the configuration where the numbers of anti-nodes AN and nodes ND in the last barrier layer are increased, that is, the configuration where N_{ND} and/or N_{AN} are 2 or more.

Therefore, in the case where the numbers of anti-nodes AN and nodes ND in the last barrier layer are insufficient (Comparative Example 1), or in the case where the numbers of anti-nodes AN and nodes ND in the p-region are too large (Comparative Example 2), there is no effect. However, when the above-described first and second conditions are satisfied, the switching of the hole injection occurs, and the reduction of the efficiency of the surface emitting laser due to carrier heterogeneity between the respective well layers of the quantum well active layer can be eliminated, providing a high-efficiency surface emitting laser.

### Second Embodiment

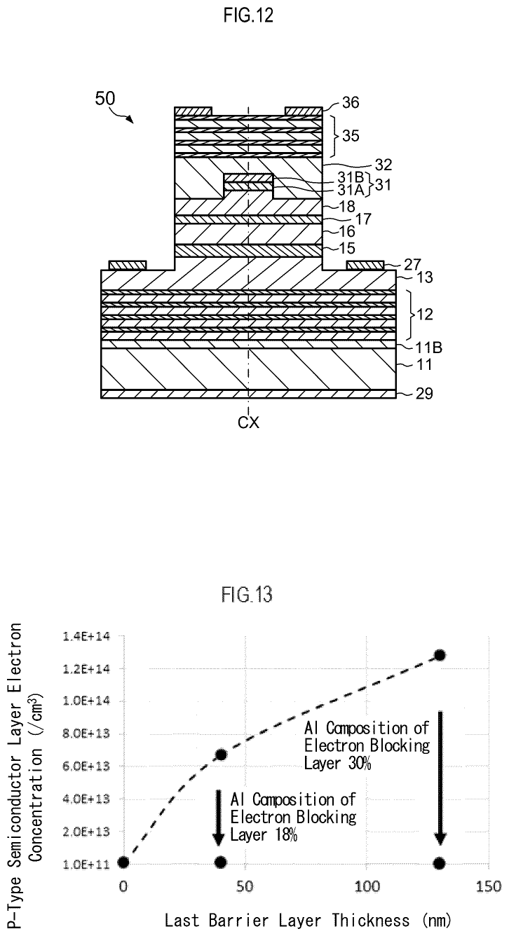

FIG. 12 is a cross-sectional view schematically illustrating a structure of a vertical cavity surface emitting laser 50 according to a second embodiment of the present invention. The vertical cavity surface emitting laser 50 of this embodiment has a tunnel junction as a current confinement structure.

The vertical cavity surface emitting laser 50 is a nitride surface emitting laser with a configuration similar to that of Example 1 of the vertical cavity surface emitting laser 10 according to the first embodiment.

That is, the vertical cavity surface emitting laser 50 is formed by crystal growth of the semiconductor DBR 12, the n-type semiconductor layer 13, the active layer 15 made of multiple quantum wells, the last barrier layer 16, the electron blocking layer (EBL) 17, and the p-type semiconductor layer 18 on the substrate 11 sequentially in this order. In addition, the composition, layer thickness, impurity concentration, and the like of each semiconductor layer are similar to those of the vertical cavity surface emitting laser 10.

In the vertical cavity surface emitting laser 50 according to the second embodiment, after the p-type semiconductor layer 18 is grown, a tunnel junction layer 31 made of a p-type semiconductor layer 31A made of p⁺-GaN with high impurity concentration and an n-type semiconductor layer 31B made of n⁺-GaN with high impurity concentration is grown.

Next, the tunnel junction layer 31 and the p-type semiconductor layer 18 are etched in a cylindrical shape to reach from an upper surface of the tunnel junction layer 31 to the inside of the p-type semiconductor layer 18, forming a cylindrical mesa structure.

For example, the tunnel junction layer 31 has a layer thickness of 20 nm, and the cylindrical mesa structure has a diameter of 4 μm (central axis CX). In addition, dry etching is used to form the mesa structure, and the tunnel junction layer 31 and the p-type semiconductor layer 18 are etched, for example, at a depth of 25 nm.

Then, an n-type semiconductor layer 32 (second n-type semiconductor layer) made of n-GaN is grown again using an MOVPE apparatus, and the tunnel junction layer 31 is embedded.

Subsequently, a semiconductor DBR 35 (second DBR) made of n-AlInN and n-GaN is formed. The semiconductor DBR 35 is made of, for example, 46 pairs of n-AlInN/GaN.

Next, an outer peripheral portion of the wafer was etched to reach the inside of the n-type semiconductor layer 13, forming a surface emitting laser with a cylindrical mesa structure coaxial with the central axis CX of the tunnel junction layer 31.

Next, the n-electrode 27 was formed on a surface of the outer peripheral portion of the n-type semiconductor layer 13. In a top view (when viewed from a direction perpendicular to the semiconductor DBR 35), a p-electrode 36 having a diameter larger than the tunnel junction layer 31 and a circular opening coaxial with the central axis CX was formed on the semiconductor DBR 35.

Furthermore, the backside surface of the substrate 11 was polished to form the AR (non-reflective) coating 29 made of two layers of Nb₂O₅/SiO₂. As described above, the formation of the vertical cavity surface emitting laser 50 was completed.

Although the tunnel junction layer 31 was constituted of the p⁺-GaN layer and the n⁺-GaN layer, semiconductor layers of other compositions, such as GaInN, may be used. The p⁺-GaN layer can, for example, employ Mg as impurities (dopant). In addition, the doping concentration of Mg is preferably 4×10¹⁹ cm³ or more. For the n⁺-GaN layer or n⁺-GaInN layer, high doping of 1×10¹⁸ cm³ or more is preferred.

[Correspondence Relationship with First Embodiment]

The first and second conditions in the vertical cavity surface emitting laser 50 according to the second embodiment can be considered similarly to the case of the first embodiment.

Specifically, in the vertical cavity surface emitting laser 50 according to the second embodiment, an interface between the semiconductor DBR 35 and the n-type semiconductor layer 32 corresponds to the phase reference (0). The anti-nodes of the standing wave are positioned at the reference.

The n-type semiconductor layer 32 (second n-type semiconductor layer) corresponds to the spacer layer 24 in the first embodiment. More specifically, a part of the n-type semiconductor layer 32 between the tunnel junction layer 31 and the semiconductor DBR 35 corresponds to the spacer layer 24 in the first embodiment.

Furthermore, the tunnel junction layer 31 corresponds to the transparent conductive film (ITO) 22 in the first embodiment, and one node ND of the standing wave SW is preferably present (N_{ND}=1) in the tunnel junction layer 31.

The condition for the numbers of nodes ND and anti-nodes AN of the standing wave SW contained in the electron blocking layer 17 and the p-type semiconductor layer 18 that serve as the p-region (the first condition) and the condition for the numbers of nodes ND and anti-nodes AN contained in the last barrier layer 16 (the second condition) are the same as the conditions in the first embodiment.

In the above-described examples, the numbers of anti-nodes and nodes of the standing wave contained in the p-type semiconductor layer 18 and the electron blocking layer 17, and the layer thickness of each layer based on the numbers of nodes and anti-nodes of the standing wave contained in the last barrier layer 16 have been described.

Based on the conditions that have been described, the thickness t1 of the last barrier layer 16 must be at least a certain thickness. However, the inventor of this application found that if only the thickness of the last barrier layer 16 is enlarged while maintaining the Al composition of the electron blocking layer 17, a potential drop occurs in the last barrier layer 16, the effectiveness of the last barrier layer 16 and the electron blocking layer 17 as barrier layers decreases, and the efficiency of electron injection into the active layer 15 decreases.

In order to maintain the function of the last barrier layer 16 and the electron blocking layer 17 as barrier layers, the Al composition of the electron blocking layer 17 is preferably set to a higher value as the thickness of the last barrier layer 16 increases.

FIG. 13 shows a graph of a change in the electron concentration of the p-type semiconductor layer 18 caused by a potential drop arising from the increase in the thickness of the last barrier layer 16. In the graph of FIG. 13, the horizontal axis is the thickness of the last barrier layer 16, and the vertical axis is the electron concentration of the p-type semiconductor layer 18. In addition, this graph shows the case where the Al composition of the electron blocking layer 17 is fixed at 13%. Note that the numerical notation of, for example, “1.0E+11” and the like on the vertical axis of the p-type semiconductor layer electron concentration in FIG. 13 means “1.0×10¹¹” and the like.

As indicated in the graph, the electron concentration of the p-type semiconductor layer 18, which is 1.0×10¹¹ in the absence of the last barrier layer 16, is 6.7×10¹³ when the thickness of the last barrier layer 16 becomes 40 nm, and it is 1.28×10¹⁴ when the thickness of the last barrier layer 16 becomes 130 nm. This graph can also tell the influence of the potential drop due to the thickening of the last barrier layer 16.

The inventor of this application has found that in order to reduce the electron concentration of the p-type semiconductor layer 18 to 1.0×10¹¹, which is the value in the absence of the last barrier layer 16, the Al composition of the electron blocking layer 17 should be 18% when the thickness of the last barrier layer 16 is 40 nm and should be 30% when the thickness of the last barrier layer 16 is 130 nm.

From this, it was found that in order to maintain the barrier effect by the last barrier layer 16 and the electron blocking layer 17 while increasing the thickness of the last barrier layer 16, when the layer thickness of the last barrier layer 16 is 40 nm or more, it is preferred that the relationship of Y≥0.13X+12.7 is satisfied, where X is the film thickness t1 of the last barrier layer 16, and Y is an average Al composition of the electron blocking layer 17 in %. Hereinafter, the fact that the relationship of Y≥0.13X+12.7 is satisfied means that Relationship 1 is satisfied.

Meanwhile, when the Al composition of the electron blocking layer 17 is increased, cracks easily occur in the electron blocking layer 17. In response to this, in order to avoid cracks while maintaining the Al composition of the electron blocking layer 17 to maintain the electron injection efficiency, it was found that it is effective to configure the electron blocking layer 17 to increase its Al composition on the active layer 15 side and reduce its Al composition on the p-type semiconductor layer 18 side.

Specifically, for example, it is considered to configure the electron blocking layer 17 by two layers with different Al compositions of a first layer adjacent to the last barrier layer 16, that is, on the active layer 15 side, and a second layer adjacent to the p-type semiconductor layer 18, that is, on the p-type semiconductor layer 18 side, which has a smaller Al composition than the first layer.

Furthermore, it was found that when the electron blocking layer 17 is constituted of two layers with different Al compositions, the Al compositions are preferably set such that Y1>Y2 and Y1≥0.13X+17.5, where X is the film thickness t1 of the last barrier layer 16, and Y1 is the average Al composition of the first layer on the active layer 15 side of the electron blocking layer 17 in %, and such that Y2≥0.13X+5.5, where Y2 is the average Al composition of the second layer on the p-type semiconductor layer 18 side of the electron blocking layer 17 in %. Hereinafter, the fact that the relationships of Y1≥0.13X+17.5 and Y2≥0.13X+5.5 is satisfied means that Relationship 2 is satisfied.

TABLE 2

| | | Average | Average | Average | |
|---|---|---|---|---|---|
| | Last | Al Composition | Al Composition | Al Composition | |
| | barrier | of Entire Electron | of First Layer | of Second Layer | |
| | Layer | Blocking Layer | (Layer Thickness 6 nm) | (Layer Thickness 4 nm) | Injection |
| | Thickness | (Layer Thickness 10 nm) | of Electron Blocking | of Electron Blocking | Efficiency |
| | (nm) | (%) | Layer (%) | Layer (%) | (%) |
| Sample 1 | 130 | 30 | — | — | 71 |
| Comparative | 130 | 15 | — | — | 40 |
| Example 1 | | | | | |
| Comparative | 40 | 15 | — | — | 55 |
| Example 2 | | | | | |
| Comparative | 10 | 15 | — | — | 70 |
| Example 3 | | | | | |
| Sample 2 | 130 | 30 | 35 | 23 | 75 |
| Sample 3 | 40 | 18 | 23 | 11 | 79 |

Table 2 is a table showing the film thickness of the last barrier layer 16, the average Al composition of the electron blocking layer 17 and electron injection efficiency for Sample 1, which is a vertical cavity surface emitting laser 10 satisfying Relationship 1 described above, Sample 2 and Sample 3 satisfying Relationships 1 and 2, and Comparative Examples 1 to 3. Sample 1, Sample 2, Sample 3, and Comparative Examples 1 to 3 all share a commonality, except for the layer thickness of the last barrier layer 16 and the configuration of the electron blocking layer 17. In addition, the layer thickness of the electron blocking layer 17 for Sample 1, Sample 2, Sample 3, and Comparative Examples 1 to 3 is 10 nm.

In Sample 1, the layer thickness of the last barrier layer 16 is 130 nm, and the average Al composition of the electron blocking layer 17 is 30% satisfying Relationship 1. In Sample 2, the layer thickness of the last barrier layer 16 is 130 nm. The average Al composition of the electron blocking layer 17 satisfies Relationship 1, and the average Al composition of the first layer and the average Al composition of the second layer of the electron blocking layer 17 are 35% and 23%, respectively, satisfying Relationship 2. In Sample 3, the film thickness of the last barrier layer 16 is 40 nm. The average Al composition of the electron blocking layer 17 satisfies Relationship 1, and the average Al composition of the first layer and the average Al composition of the second layer of the electron blocking layer 17 are 23% and 11%, respectively, satisfying Relationship 2.

In Comparative Examples 1 to 3, the electron blocking layers have an Al composition of 15%, and the layer thicknesses of the last barrier layers are 130 nm, 40 nm, and 10 nm, respectively. As described above and indicated in Table 2, it can be seen that the injection efficiency decreases as the layer thickness of the last barrier layer is thickened. On the other hand, it was confirmed that when the last barrier layer is 130 nm, the injection efficiency was significantly improved in Sample 1, compared with Comparative Example 1, and it became similar to that of Comparative Example 3 with a thinner last barrier layer 16 that had a layer thickness of the last barrier layer 16 of 10 nm.

As described above, increasing the Al composition of the electron blocking layer 17 tends to cause cracking. To avoid this, in Sample 2 and Sample 3, the first layer with a high Al composition was formed on the active layer 15 side of the electron blocking layer 17, and the layer with a low Al composition was formed on the p-type semiconductor layer 18 side of the electron blocking layer 17. The average Al composition of the entire electron blocking layer 17 of Sample 2 is 30%, which is identical to that of Sample 1.

In Sample 2 and Sample 3, the injection efficiency obtained was better than that of Sample 1, and the electron blocking layer 17 was made of two layers, thereby having an unchanged effect of the improvement of the injection efficiency. Rather, it was found that the injection efficiency was higher than that in the case where the Al composition of the electron blocking layer 17 was uniform.

From the result of Sample 2, it can be seen that when the layer thickness of the last barrier layer is 130 nm, satisfactory injection efficiency can be obtained as long as the Al composition of the first layer of the electron blocking layer 17 is 35% or more and the Al composition of the second layer is 23% or more. From the result of Sample 3, it can be seen that when the layer thickness of the last barrier layer is 40 nm, satisfactory injection efficiency can be obtained as long as the Al composition of the first layer of the electron blocking layer 17 is 23% or more and the Al composition of the second layer is 11% or more.

Relationship 2 of the preferable Al composition setting values described above, that is, the relationship that maintains the electron injection efficiency well when Y1>Y2, Y1≥0.13X+17.5, and Y2≥0.13X+5.5, is derived from the layer thickness of the last barrier layer and the Al compositions of the first layer and the second layer of the electron blocking layer 17 in Samples 2 and 3, which exhibited satisfactory injection efficiency.

As described above, it was found that the vertical cavity surface emitting laser 10 can be configured while maintaining the efficiency of electron injection into the active layer 15 by setting the Al composition Y % of the electron blocking layer 17 such that the relationship of Y≥0.13X+12.7 is satisfied, where X is the thickness of the last barrier layer 16 in nm and when X is thicker than 40 nm.

Furthermore, it was found that the vertical cavity surface emitting laser 10 can be configured while maintaining the efficiency of electron injection into the active layer 15 and avoiding cracking to the electron blocking layer 17 by forming the electron blocking layer 17 of two layers with different Al compositions, setting the Al composition Y1% of the first layer close to the active layer 15 such that Y1≥0.13X+17.5, where X is the thickness of the last barrier layer 16 in nm, and setting the AI composition Y2% of the second layer such that Y2≥0.13X+5.5.

The higher the Al composition of the electron blocking layer 17 and the thicker the layer thickness of the electron blocking layer 17, the easier it is to occur cracks in the electron blocking layer 17. In addition, although it cannot be said unambiguously because it also depends on the growth temperature of the electron blocking layer, the width and rate of the temperature rise and decrease after crystal growth, and the like, the inventor of this application has found that crack generation can be reduced to a practical level by, for example, setting the product of the Al composition (%) of the electron blocking layer 17 and the layer thickness (nm) of the electron blocking layer 17 to 500% nm or less. That is, the inventor of this application has found that the relationship of Y×Z≤500 is preferably satisfied, where Y is the Al composition of the electron blocking layer 17 in %, and Z is the thickness of the electron blocking layer 17 in nm.

As described in detail above, according to the present invention, a vertical cavity light-emitting element with a low threshold current and high light-emitting efficiency can be provided.

While vertical cavity light-emitting elements using nitride semiconductors have been described in the above examples, the present invention can also be applied to vertical cavity light-emitting elements using other crystalline semiconductors.

In addition, the semiconductor DBR or dielectric DBR was illustrated as an example as a reflective mirror constituting a resonator, but the reflective mirror is not limited to them. For example, a single-layer reflective mirror or diffraction grating can be used.

The vertical cavity light-emitting element of the present invention has been described using the case where it is manufactured using the MOVPE method as an example, but it can be manufactured by other known crystal growth methods, such as the molecular beam epitaxy (MBE) method.

### DESCRIPTION OF REFERENCE SIGNS

10 Vertical cavity surface emitting laser
11 Substrate
12 DBR (reflective mirror)
13 n-type semiconductor layer
15 Active layer
15B Blocking layer (barrier layer)
15W Quantum well layer (well layer)
16 Last barrier layer (LB)
17 Electron blocking layer
18 p-type semiconductor layer
21 Insulating film
22 Transparent conductive film
24 Spacer layer
25 DBR (reflective mirror)
31 Tunnel junction layer
31A p-type semiconductor layer with high impurity concentration
31B n-type semiconductor layer with high impurity concentration
32 n-type semiconductor layer (second n-type semiconductor layer)
35 Semiconductor DBR

1. A vertical cavity light-emitting element comprising:
a first reflective mirror;
an n-type semiconductor layer formed on the first reflective mirror;
an active layer made of multiple quantum wells formed on the n-type semiconductor layer;
a last barrier layer formed on a last quantum well of the active layer;
an electron blocking layer made of AlGaN formed on the last barrier layer;
a p-type semiconductor layer formed on the electron blocking layer;
a dielectric spacer layer formed on the p-type semiconductor layer; and
a second reflective mirror formed on the spacer layer, wherein
a count of anti-nodes and a count of nodes of a standing wave by emission from the active layer contained in the electron blocking layer and the p-type semiconductor layer are each 0 or 1,
the active layer and the last barrier layer satisfy
$$[ Math . 1 ]$$
$$\frac{{H}_{qw}}{2 ( \frac{λ}{{n}_{qw}} )} + \frac{{H}_{fb}}{( \frac{λ}{{n}_{fb}} )} \geq 0.4$$
$$where$$
$${n}_{qw} = \frac{\sum {n}_{i} \times \sum {H}_{i}}{\sum {H}_{i}}$$
where H_{fb} and H_{qw} are respective layer thicknesses of the last barrier layer and the active layer, n_{fb} is a refractive index of the last barrier layer, and n_{qw} is an equivalent refractive index of the active layer, and Y≥0.13X+12.7 is satisfied, where X is a layer thickness of the last barrier layer in nm, and Y is an average Al composition of the electron blocking layer in %.

2. The vertical cavity light-emitting element according to claim 1, wherein
the electron blocking layer includes a first AlGaN layer arranged on the active layer side and a second AlGaN layer arranged on the p-type semiconductor layer side,
an Al composition Y1% of the first AlGaN layer is larger than an Al composition Y2% of the second AlGaN layer, and
Y1≥0.13X+17.5 and Y2≥0.13X+5.5 is satisfied.

3. The vertical cavity light-emitting element according to claim 1, wherein
ZY≤500 is satisfied, where Z is a film thickness of the electron blocking layer in nm.

4. The vertical cavity light-emitting element according to claim 1, wherein
counts of nodes and anti-nodes of the standing wave contained in the last barrier layer are each 1 or more.

5. The vertical cavity light-emitting element according to claim 1, comprising
a transparent conductive film disposed between the p-type semiconductor layer and the dielectric spacer layer, wherein
the transparent conductive film is disposed such that a node of the standing wave is present in the transparent conductive film.

6. The vertical cavity light-emitting element according to claim 1, wherein
the last barrier layer has a layer thickness of λ/4 (λ: wavelength in a medium) or more.

7. The vertical cavity light-emitting element according to claim 1, wherein
a count of nodes contained in the last barrier layer is 2 or more, and a count of anti-nodes contained in the last barrier layer is 1 or more.

8. The vertical cavity light-emitting element according to claim 1, wherein
the active layer has a layer thickness of λ/8 (γ: wavelength in a medium) or less.

9. The vertical cavity light-emitting element according to claim 1, wherein
the vertical cavity light-emitting element has a local minimal value of differential resistance caused by laser oscillation near a threshold current.

10. The vertical cavity light-emitting element according to claim 1, wherein
the first reflective mirror is a semiconductor distributed Bragg reflector (DBR), and the second reflective mirror is a dielectric DBR.

11. A vertical cavity light-emitting element comprising:
a first reflective mirror;
a first n-type semiconductor layer formed on the first reflective mirror;
an active layer made of multiple quantum wells formed on the first n-type semiconductor layer;
a last barrier layer formed on a last quantum well of the active layer;
an electron blocking layer made of AlGaN formed on the last barrier layer;
a p-type semiconductor layer formed on the electron blocking layer;
a tunnel junction layer as a current confinement layer formed on the p-type semiconductor layer;
a second n-type semiconductor layer formed by embedding the tunnel junction layer; and
a second reflective mirror formed on the second n-type semiconductor layer, wherein a count of anti-nodes and a count of nodes of a standing wave by emission from the active layer contained in the electron blocking layer and the p-type semiconductor layer are each 0 or 1,
the active layer and the last barrier layer satisfy
$$[ Math . 2 ]$$
$$\frac{{H}_{qw}}{2 ( \frac{λ}{{n}_{qw}} )} + \frac{{H}_{fb}}{( \frac{λ}{{n}_{fb}} )} \geq 0.4$$
$$where$$
$${n}_{qw} = \frac{\sum {n}_{i} \times \sum {H}_{i}}{\sum {H}_{i}}$$
where H_{fb} and H_{qw} are respective layer thicknesses of the last barrier layer and the active layer, n is a refractive index of the last barrier layer, and n_{qw} is an equivalent refractive index of the active layer, and Y≥0.13X+12.7 is satisfied, where X is a layer thickness of the last barrier layer in nm, and Y is an average Al composition of the electron blocking layer in %.

12. The vertical cavity light-emitting element according to claim 11, wherein
the electron blocking layer includes a first AlGaN layer arranged on the active layer side and a second AlGaN layer arranged on the p-type semiconductor layer side,
an Al composition Y1% of the first AlGaN layer is larger than an Al composition Y2% of the second AlGaN layer, and
Y1≥0.13X+17.5 and Y2≥0.13X+5.5 is satisfied.

13. The vertical cavity light-emitting element according to claim 11, wherein
ZY≤500 is satisfied, where Z is a film thickness of the electron blocking layer in nm.

14. The vertical cavity light-emitting element according to claim 11, wherein
counts of nodes and anti-nodes of the standing wave contained in the last barrier layer are each 1 or more.

15. The vertical cavity light-emitting element according to claim 11, wherein
the tunnel junction layer is disposed such that a node of the standing wave is present in the tunnel junction layer.

16. The vertical cavity light-emitting element according to claim 11, wherein
the last barrier layer has a layer thickness of λ/4 (λ: wavelength in a medium) or more.

17. The vertical cavity light-emitting element according to claim 11, wherein
a count of nodes contained in the last barrier layer is 2 or more, and a count of anti-nodes contained in the last barrier layer is 1 or more.

18. The vertical cavity light-emitting element according to claim 11, wherein
the active layer has a layer thickness of λ/8 (λ: wavelength in a medium) or less.

19. The vertical cavity light-emitting element according to claim 11, wherein
the vertical cavity light-emitting element has a local minimal value of differential resistance caused by laser oscillation near a threshold current.

20. The vertical cavity light-emitting element according to claim 11, wherein
the first reflective mirror and the second reflective mirror are semiconductor DBRs.
